(19) United States
(12) Patent Application Publication
(10) Pub. No.: US 2024/0079340 A1
(43) Pub. Date: Mar. 7, 2024

(54) SEMICONDUCTOR PACKAGE

(71) Applicant: SAMSUNG ELECTRONICS CO., LTD., SUWON-SI (KR)

(72) Inventors: Hyunsoo CHUNG, Suwon-si (KR); Younglyong KIM, Suwon-si (KR); Inhyo HWANG, Suwon-si (KR)

(21) Appl. No.: 18/459,520

(22) Filed: Sep. 1, 2023

(30) Foreign Application Priority Data
Sep. 1, 2022 (KR) 10-2022-0111016

(51) Int. Cl. H01L 23/538; H01L 23/00; H01L 23/498; H01L 25/065; H10B 80/00

(52) U.S. Cl. CPC H01L 23/5386; H01L 23/49811; H01L 24/16; H01L 24/29; H01L 24/30; H01L 24/32; H01L 24/33; H01L 24/73; H01L 25/0652; H10B 80/00; H01L 2224/16146; H01L 2224/16227; H01L 2224/2919; H01L 2224/30505; H01L 2224/32146; H01L 2224/32225; H01L 2224/33051; H01L 2224/73204; H01L 2224/73253; H01L 2225/065; H01L 2924/1436; H01L 2924/2064; H01L 2924/2065

(57) ABSTRACT

A semiconductor package includes: a base substrate; an interposer disposed on the base substrate, wherein the interposer includes a plurality of recesses in a bottom surface thereof; a semiconductor chip disposed on the interposer; a plurality of interposer connection terminals between the interposer and the base substrate, wherein the plurality of interposer connection terminals electrically connect the interposer to the base substrate; and a first underfill layer disposed between the interposer and the base substrate, wherein the first underfill layer at least partially surrounds the plurality of interposer connection terminals, wherein the first underfill layer at least partially surrounds a side surface of each of the plurality of recesses and has a slope declining from the bottom surface of the interposer to a top surface of the base substrate.

### CROSS-REFERENCE TO RELATED APPLICATION

This application claims priority under 35 U.S.C. § 119 to Korean Patent Application No. 10-2022-0111016, filed on Sep. 1, 2022, in the Korean Intellectual Property Office, the disclosure of which is incorporated by reference herein in its entirety.

### TECHNICAL FIELD

The present inventive concept relates to a semiconductor package.

### DISCUSSION OF THE RELATED ART

With the increased demand for compact and multifunctionalized high-performance electronic products, semiconductor packages are desired to be light and highly integrated and to have relatively high performance and speed. Therefore, there is increasing demand for semiconductor packages for systems that have a high memory bandwidth.

Because the memory bandwidth is proportional to the data transfer rate and the number of data transmission lines, the memory bandwidth may be increased by increasing the memory operation speed or the number of data transmission lines. Accordingly, semiconductor packages that use an interposer have been under development to increase the number and density of connection bumps attached to connection pads of semiconductor chips.

### SUMMARY

According to an embodiment of the present inventive concept, a semiconductor package includes: a base substrate; an interposer disposed on the base substrate, wherein the interposer includes a plurality of recesses in a bottom surface thereof; a semiconductor chip disposed on the interposer; a plurality of interposer connection terminals between the interposer and the base substrate, wherein the plurality of interposer connection terminals electrically connect the interposer to the base substrate; and a first underfill layer disposed between the interposer and the base substrate, wherein the first underfill layer at least partially surrounds the plurality of interposer connection terminals, wherein the first underfill layer at least partially surrounds a side surface of each of the plurality of recesses and has a slope declining from the bottom surface of the interposer to a top surface of the base substrate.

According to an embodiment of the present inventive concept, a semiconductor package includes: a base substrate; an interposer disposed on the base substrate, wherein the interposer includes a plurality of recesses in a bottom surface thereof; a core die stack disposed on the interposer; a plurality of interposer connection terminals disposed between the interposer and the base substrate, wherein the plurality of interposer connection terminals electrically connect the interposer to the base substrate; a first underfill layer disposed between the interposer and the base substrate, wherein the first underfill layer at least partially surrounds the plurality of interposer connection terminals; and a second underfill layer disposed between the base substrate and the interposer, wherein the second underfill layer at least partially surrounds a side surface of the first underfill layer, wherein each of the plurality of recesses is formed in a lower corner of the interposer and is defined by a first surface and a second surface of the interposer, wherein the first and second surfaces extend in different directions from each other, and the second surface of each of the plurality of recesses has a step difference with respect to the bottom surface of the interposer and faces the base substrate, a side wall of the interposer protrudes beyond a side wall of the first underfill layer in a lateral direction, and a width of the second surface is about 800 μm to about 1,200 μm.

According to an embodiment of the present inventive concept, a semiconductor package includes: a base substrate; a silicon interposer attached to the base substrate and including a plurality of recesses, wherein each of the plurality of recesses includes a first surface and a second surface, wherein the first surface is substantially perpendicular to a first direction, and wherein the second surface has a step difference from a bottom surface of the silicon interposer and faces the base substrate; at least one stack structure attached to the silicon interposer and including a first semiconductor chip and a plurality of second semiconductor chips stacked on the first semiconductor chip in a vertical direction, wherein the first semiconductor chip includes a first semiconductor substrate and a plurality of first through electrodes passing through the first semiconductor substrate, and wherein each of the plurality of second semiconductor chips includes a second semiconductor substrate and a plurality of second through electrodes electrically connected to the plurality of first through electrodes; a plurality of third semiconductor chips attached to the silicon interposer and separated from the at least one stack structure in a horizontal direction; a first underfill layer disposed between the silicon interposer and the base substrate, wherein the first underfill layer bonds the silicon interposer to the base substrate and includes a first underfill layer contact surface contacting the second surface of each of the plurality of recesses; and a second underfill layer at least partially surrounding a side surface of the first underfill layer, wherein the step difference of the second surface is less than or equal to half of a thickness of the silicon interposer.

### BRIEF DESCRIPTION OF THE DRAWINGS

The above and other aspects of the present inventive concept will become more apparent by describing in detail embodiments thereof, with reference to the accompanying drawings, in which:

FIG. 1 is a cross-sectional view of a semiconductor package according to an embodiment of the present inventive concept;

FIG. 2 is an enlarged cross-sectional view of a region EX1 in FIG. 1;

FIGS. 3, 4, 5 and 6 are cross-sectional views illustrating semiconductor packages and enlarged cross-sectional views of a region EX2 in FIG. 1, according to some embodiments of the present inventive concept;

FIG. 7 is a flowchart of a method of manufacturing a semiconductor package; according to an embodiment of the present inventive concept;

FIGS. 8, 9, 10, 11 and 12 are cross-sectional views showing stages in a method of manufacturing a semiconductor package, according to an embodiment of the present inventive concept; and

FIG. 13 is a block diagram of a system of a semiconductor package, according to an embodiment of the present inventive concept.

### DETAILED DESCRIPTION OF THE EMBODIMENTS

Hereinafter, embodiments of the present inventive concept are described in detail with reference to the accompanying drawings. In the drawing, like reference characters denote like elements, and redundant descriptions thereof may be omitted or briefly discussed.

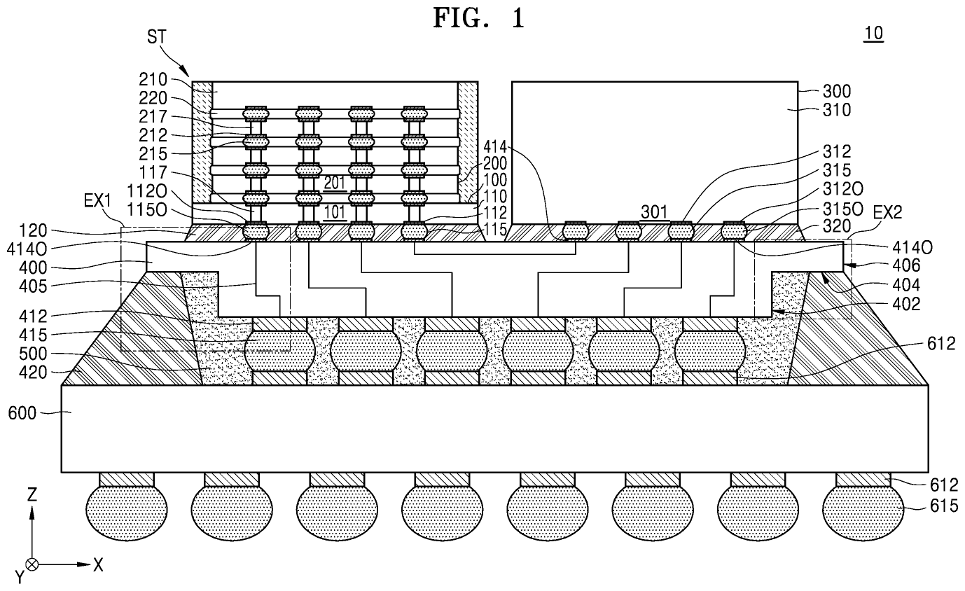

FIG. 1 is a cross-sectional view of a semiconductor package according to an embodiment of the present inventive concept.

Referring to FIG. 1, a semiconductor package 10 may include at least one stack structure ST including a first semiconductor chip 100 and a plurality of second semiconductor chips 200 stacked on the first semiconductor chip 100, an interposer 400, a plurality of third semiconductor chips 300 attached to the interposer 400, a first underfill layer 500, a package molding layer (including a second underfill layer 420 and a third underfill layer 120), and a base substrate 600. According to some embodiments of the present inventive concept, the semiconductor package 10 of FIG. 1 may correspond to high bandwidth memory (HBM) including a plurality of dynamic random access memory (DRAM) chips and a logic chip.

The stack structure ST may include the first semiconductor chip 100 and a plurality second semiconductor chips 200. Although it is illustrated in FIG. 1 that the stack structure ST includes one first semiconductor chip 100 and four second semiconductor chips 200, the present inventive concept is not necessarily limited thereto. The stack structure ST may include a core die stack.

For example, the stack structure ST may include at least two second semiconductor chips 200. In some embodiments of the present inventive concept, the stack structure ST may include a multiple of 4 second semiconductor chips 200. The second semiconductor chips 200 may be sequentially stacked on the first semiconductor chip 100 in a vertical direction. The first semiconductor chip 100 and the second semiconductor chips 200 may be sequentially stacked such that the respective active surfaces thereof face downwards, e.g., toward the interposer 400.

In some embodiments of the present inventive concept, the first semiconductor chip 100 may correspond to a buffer chip or HBM control die, which controls FIRM DRAM, and each of the second semiconductor chips 200 may correspond to a memory cell chip or DRAM die, which includes cells of the HBM DRAM controlled by the first semiconductor chip 100. The first semiconductor chip 100 may be referred to as a buffer chip or a master chip, and each of the second semiconductor chips 200 may be referred to as a slave chip or a memory cell chip. The stack structure ST including the first semiconductor chip 100 and the second semiconductor chips 200 sequentially stacked on the first semiconductor chip 100 may be referred to as an FIRM DRAM device.

Each of the first and second semiconductor chips 100 and 200 may include DRAM, static RAM (SRAM), flash memory, electrically erasable and programmable read-only memory (EEPROM), phase-change RAM (PRAM), magnetic RAM (MRAM), or resistive RAM (RRAM).

In some embodiments of the present inventive concept, the first semiconductor chip 100 might not include a memory cell. The first semiconductor chip 100 may include, for example, a serial-to-parallel conversion circuit, a test logic circuit, such as a design-for-test (DFT) circuit, a. Joint Test Action Group (JTAG) circuit, or a memory built-in self-test (MBIST) circuit, or a signal interface circuit such as a PHY. The second semiconductor chips 200 may include a memory cell. For example, the first semiconductor chip 100 may correspond to a buffer chip controlling the second semiconductor chips 200.

The horizontal width and area of the first semiconductor chip 100 may be greater than those of each of the second semiconductor chips 200. For example, the entireties of each of the second semiconductor chips 200 may overlap with the first semiconductor chip 100 in the vertical direction. In some embodiments of the present inventive concept, the second semiconductor chips 200 may completely overlap with each other in the vertical direction. For example, the second semiconductor chips 200 may be aligned or misaligned with each other.

The first semiconductor chip 100 may include a first substrate 110, a plurality of first connection pads 112, and a plurality of first through electrodes 117. Each of the second semiconductor chips 200 may include a second substrate 210, a plurality of second connection pads 212, and a plurality of second through electrodes 217, The first connection pads 112 may include a plurality of first front connection pads, which are on the front side of the first substrate 110, and a plurality of first back connection pads, which are on the back side of the first substrate 110. The second connection pads 212 may include a plurality of second front connection pads, which are on the front side of the second substrate 210, and a plurality of second back connection pads, on the back side of the second substrate 210.

The first substrate 110 and the second substrate 210 may each include silicon (Si). In addition, the first substrate 110 and the second substrate 210 may each include a semiconductor element, e.g., germanium (Ge), or a compound semiconductor, such as silicon carbide (SiC), gallium arsenide (GaAs), indium arsenide (InAs), or indium phosphide (InP). Each of the first and second substrates 110 and 210 may include an active surface and an inactive surface opposite to the active surface. Each of the first and second substrates 110 and 210 may include various kinds of individual devices on the active surface thereof. The individual devices may include various microelectronic devices, e.g., a metal-oxide-semiconductor field effect transistor (MOSFET) such as complementary metal-oxide-semiconductor (CMOS) transistor, a system large scale integration (LSI), an image sensor such as a CMOS image sensor (CIS), a micro-electro-mechanical system (MEMS), an active element, and a passive element. The active surface and the inactive surface of the first substrate 110 may be respectively referred to as a first active surface and a first inactive surface, and the active surface and the inactive surface of the second substrate 210 may be respectively referred to as a second active surface and a second inactive surface.

The first semiconductor chip 100 may include a first semiconductor device 101 including a plurality of individual devices, and each of the second semiconductor chip 200 may include a second semiconductor device 201 including a plurality of individual devices. The first semiconductor device 101 may be on the first active surface of the first substrate 110. The first front connection pads may be on the first active surface of the first substrate 110, and the first back connection pads may be on the first inactive surface of the first substrate 110. The first through electrodes 117 may vertically pass through at least a portion of the first substrate 110 and respectively and electrically connect the first front connection pads to the first back connection pads.

The second semiconductor device 201 may be on the second active surface of the second substrate 210. The second front connection pads may be on the second active surface of the second substrate 210, and the second back connection pads may be on the second inactive surface of the second substrate 210. The second through electrodes 217 may vertically pass through at least a portion of the second substrate 210 and respectively and electrically connect the second front connection pads to the second back connection pads. The second through electrodes 217 may be electrically connected to the first through electrodes 117.

An insulating adhesive layer 220 may be between the first semiconductor chip 100 and a second semiconductor chip 200 and/or between two adjacent second semiconductor chips 200. The insulating adhesive layer 220 may be attached to the bottom surface of each of the second semiconductor chips 200, and thus, each second semiconductor chip 200 may be attached to a lower structure, e.g., the first semiconductor chip 100 or another second semiconductor chip 200 disposed below each second semiconductor chip 200. The insulating adhesive layer 220 may include, for example, a non-conductive film (NCF) (or a first underfill layer), non-conductive paste (NCP), an insulating polymer, or epoxy resin. The insulating adhesive layer 220 may at least partially surround a plurality of second chip connection terminals 215 and fill a space between the first semiconductor chip 100 and a second semiconductor chip 200 or a space between two adjacent second semiconductor chips 200.

Each of the third semiconductor chips 300 may include a third substrate 310 and a plurality of third connection pads 312. The third connection pads 312 may be on a third active surface of the third substrate 310. The third substrate 310 is substantially similar to the first and second substrates 110 and 210, and thus, detailed descriptions thereof are omitted.

The third substrate 310 may include an active surface and an inactive surface that is opposite to the active surface. The active surface and the inactive surface of the third substrate 310 may be respectively referred to as a third active surface and a third inactive surface. Each of at least some of the third semiconductor chips 300 may include a third semiconductor device 301. The third semiconductor device 301 may be on the third active surface of the third substrate 310. The third semiconductor device 301 may be electrically connected to the interposer 400 through the third connection pads 312.

For example, at least some of the third semiconductor chips 300 may include, for example, a central processor unit (CPU) chip, a graphics processor unit (GPU) chip, an application processor (AP) chip, an application specific integrated circuit (ASIC), or any other processing chip.

The interposer 400 may be on the base substrate 600. The interposer 400 may be used to implement a connection terminal (e.g., a vertical connection terminal), which connects the stack structure ST and the third semiconductor chips 300 to the base substrate 600, as a fine pitch. The interposer 400 may include a silicon interposer.

The interposer 400 may include a plurality of interposer pads 412 and 414 and a plurality of interconnection lines 405. The plurality of interposer pads 414 and 412 are disposed on the top or bottom surface of the interposer 400, and the plurality of interposer interconnection lines 405 connect the plurality of interposer pads 412 and 414 on the top and bottom surfaces of the interposer 400 to each other. The top surface of the interposer 400 may face the stack structure ST and the third semiconductor chips 300, and the bottom surface of the interposer 400 may face the top surface of the base substrate 600.

The interposer pads 414 and 412 may include a plurality of interposer bottom pads 412 and a plurality of interposer top pads 414. A plurality of first chip connection terminals 115 may be respectively attached to the interposer top pads 414. Each of the first chip connection terminals 115 may correspond to a first connection terminal. The first chip connection terminals 115 may be respectively between the first connection pads 112 and the interposer top pads 414 and may electrically connect the first semiconductor chip 100 to the interposer 400.

A plurality of interposer connection terminals 415 may be respectively attached to the interposer bottom pads 412. The interposer connection terminals 415 may be respectively between a plurality of base substrate pads 612 and the interposer bottom pads 412 and may electrically connect the interposer 400 to the base substrate 600. Electrical signals of the semiconductor package 10 may be transmitted to the base substrate 600 through the interposer interconnection lines 405 of the interposer 400. In some embodiments of the present inventive concept, each of the interposer interconnection lines 405 may include a through electrode passing through the silicon substrate of the interposer 400. In some embodiments of the present inventive concept, conductive layers and conductive vias may be disposed in the interposer 400. Electrical signals of the semiconductor package 10 may be fanned out by the interposer 400.

The interposer 400 may include a plurality of recesses in the bottom thereof. The recesses may be respectively formed in corners of the interposer 400. For example, each recess may extend along an edge of the interposer 400. Each recess may be defined by the surface of the interposer 400, Each recess may be defined by first surface 402 and a second surface 404 of the interposer 400, which respectively extend in different directions. In some embodiments of the present inventive concept, the first surface 402 of the interposer 400 may be substantially perpendicular to a first direction (e.g., the X direction), and the second surface 404 of the interposer 400 may have a step difference with respect to the bottom surface of the interposer 400 and face the base substrate 600. For example, the bottom surface of the interposer 400 may be disposed at a level lower than a level of the second surface 404. For example, the second surface 404 of the interposer 400 may be in contact with the first surface 402 thereof at about a right angle. Here, the step difference of the second surface 404 of the interposer 400 and the bottom surface of the interposer 400 may be defined as the difference between the height of the second surface 404 of the interposer 400 in the vertical direction (e.g., the Z direction) and the height of the bottom surface of the interposer 400 in the vertical direction (e.g., the Z direction).

In some embodiments of the present inventive concept, the interposer 400 may include at least two recesses. In some embodiments of the present inventive concept, the interposer 400 may include at least four recesses. Each recess may include at least one first surface 402 and at least one second surface 404. The first surface 402 of the interposer 400 may correspond to a side portion of the interposer 400 and extend in a second direction (e.g., the Y direction). For example, the first surface 402 may extend in the vertical direction (e.g., the Z direction) to connect the bottom surface of the interposer 400 to the second surface 404. The second surface 404 of the interposer 400 may correspond to a bottom portion of the interposer 400 and extend in the first direction. In some embodiments of the present inventive concept, one recess or a plurality of recesses separated from each other may be provided in a side wall of the interposer 400.

The first underfill layer 500 may be between the interposer 400 and the base substrate 600. The first underfill layer 500 may at least partially surround the interposer bottom pads 412, the interposer connection terminals 415, and the base substrate pads 612. The first underfill layer 500 may include an insulating adhesive film. For example, the first underfill layer 500 may fill the gap between the interposer 400 and the base substrate 600. The first underfill layer 500 may include an insulating material.

In some embodiments of the present inventive concept, the first underfill layer 500 may cover a portion of the bottom surface of the interposer 400. In some embodiments of the present inventive concept, the first underfill layer 500 may partially cover a recess of the interposer 400. For example, the first underfill layer 500 may at least partially cover the bottom surface and the side portion, which is connected to the bottom surface, of the interposer 400, and the recess may be formed in the side portion of the interposer 400. In some embodiments of the present inventive concept, the first underfill layer 500 may completely surround the side surface of the recess of the interposer 400. Here, the side surface of the recess of the interposer 400 may correspond to the first surface 402 of the interposer 400. In some embodiments of the present inventive concept, the first underfill layer 500 may have a slope declining from the bottom surface of the interposer 400 to the top surface of the base substrate 600. The bottom width of the first underfill layer 500 may be less than the top width of the first underfill layer 500. Here, the bottom width of the first underfill layer 500 may refer to the width of a surface of the first underfill layer 500 contacting the base substrate 600, and the top width of the first underfill layer 500 may refer to the width of a surface of the first underfill layer 500 contacting the interposer 400.

In some embodiments of the present inventive concept, the first underfill layer 500 may have a slop declining from the second surface 404 of the interposer 400 to the top surface of the base substrate 600. The first underfill layer 500 may be formed by a thermal compression process. Although a side surface of the first underfill layer 500 has a linear slope in FIG. 1, the present inventive concept is not necessarily limited thereto. For example, the side surface of the first underfill layer 500 may have a convex or concave curve.

The first underfill layer 500 may cover at least a portion of the second surface 404 of a recess of the interposer 400. For example, the first underfill layer 500 may cover a portion of the second surface 404 of the interposer 400 near the first surface 402 of the interposer 400 but not another portion of the second surface 404 of the interposer 400 that is near a side wall 406 of the interposer 400.

The second underfill layer 420 may be between the base substrate 600 and the interposer 400 and may at least partially surround the side surface of the first underfill layer 500. The side wall of the second underfill layer 420 may extend from the side wall 406 of the interposer 400 to the side wall of the base substrate 600. For example, the side wall of the second underfill layer 420 that is between side wall 406 of the interposer 400 and the side wall of the base substrate 600 is slanted at an angle with respect to an upper surface of the base substrate 600. The second underfill layer 420 may fill a space between the base substrate 600 and the interposer 400, The second underfill layer 420 may include underfill resin. The second underfill layer 420 may include a different material from that of the first underfill layer 500. The second underfill layer 420 may be in contact with a portion of each of the recesses formed in the interposer 400. For example, a portion of each recess other than the portion of the recess contacting the first underfill layer 500 may be filled with the second underfill layer 420.

The semiconductor package 10 may further include the third underfill layer 120 and a fourth underfill layer 320. The third underfill layer 120 may fill a space between the first semiconductor chip 100 and the interposer 400, and the fourth underfill layer 320 may fill a space between the third semiconductor chip 300 and the interposer 400. The third underfill layer 120 and the fourth underfill layer 320 may include the same material as the second underfill layer 420. For example; the first underfill layer 500 may include a different material from that of each of the second to fourth underfill layers 420, 120, and 320.

For example, the base substrate 600 may correspond to a printed circuit board (PCB) or a ceramic substrate. When the base substrate 600 corresponds to a PCB, the base substrate 600 may include a substrate base and the base substrate pads 612.

The base substrate pads 612 may include substrate upper pads, which are on the top surface of the base substrate 600, and substrate lower pads, which are on the bottom surface of the base substrate 600. The base substrate 600 may include at least one of, for example; phenol resin, epoxy resin, and/or polyimide. For example, the base substrate 600 may include at least one of, for example, frame retardant 4 (FR4), tetrafunctional epoxy, polyphenylene ether, epoxy/polyphenylene oxide, bismaleimide triazine (BT), thermount, cyanate ester, polyimide, and/or liquid crystal polymer.

The base substrate pads 612 may include copper, nickel, stainless steel, or beryllium copper. An internal wiring, which electrically connects the substrate lower pads to the substrate lower pads; may be formed in the base substrate 600. The substrate upper pads and the substrate lower pads may be portions of a circuit wiring formed by applying a copper foil on the top and bottom surfaces of the base substrate 600 and patterning the copper foil, and the portions of the circuit wiring are exposed by solder resist layers.

External connection terminals 615 may be attached to the bottom surface of the base substrate 600. For example, the external connection terminals 615 may be respectively attached to the substrate lower pads. For example, the external connection terminals 615 may include a solder ball or a bump. The external connection terminals 615 may electrically connect the semiconductor package 10 to an external device. For example, the external connection terminals 615 may include under bump metallurgy (UBM) patterns, which are respectively on the substrate lower pads, and solder balls, which are respectively on the UBM patterns. The external connection terminals 615 may further include external connection pillars respectively between the UBM patterns and the solder balls. For example, the external connection pillars may include copper.

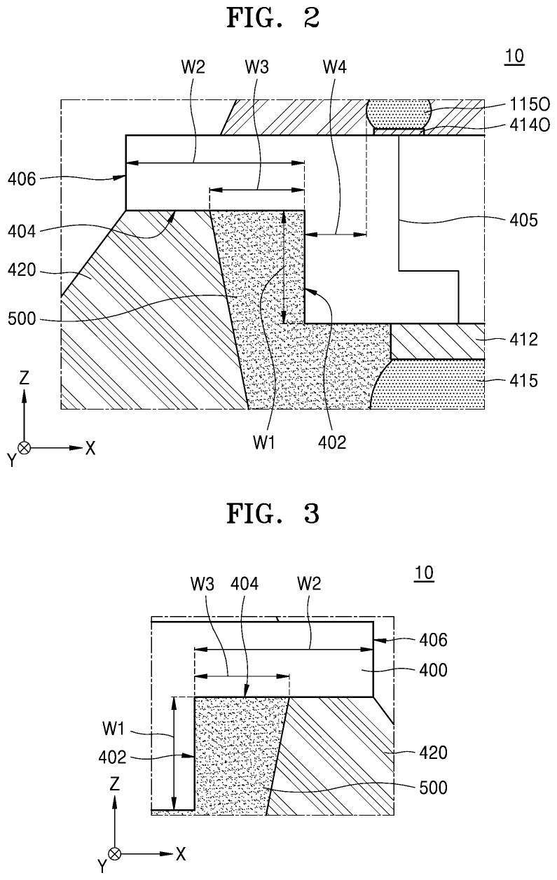

FIG. 2 is an enlarged cross-sectional view of a region EX1 in FIG. 1.

Referring to FIG. 2, a recess of the interposer 400 may include the first surface 402 and the second surface 404. The second surface 404 of the recess may have a step difference with respect to the bottom surface of the interposer 400. The step difference may be less than or equal to half the thickness of the interposer 400. The step difference between the second surface 404 of the recess and the bottom surface of the interposer 400 may be equal to a width W1 of the first surface 402.

In some embodiments of the present inventive concept, the thickness of the interposer 400 may be about 90 μm to about 130 μm. In some embodiments of the present inventive concept, the thickness of the interposer 400 may be about 100 μm to about 120 μm. In some embodiments of the present inventive concept, the step difference between the second surface 404 of the recess and the bottom surface of the interposer 400 may be less than or equal to about 65 μm. In some embodiments of the present inventive concept, the step difference between the second surface 404 of the recess and the bottom surface of the interposer 400 may be less than or equal to about 55 μm. In some embodiments of the present inventive concept, the step difference between the second surface 404 of the recess and the bottom surface of the interposer 400 may be less than or equal to about 45 μm.

The side wall 406 of the interposer 400 may protrude beyond the first underfill layer 500 in the first direction. For example, the side wall 406 of the interposer 400 may have a step difference with respect to the first surface 402 of the recess in the first direction. Here, the step difference between the side wall 406 of the interposer 400 and the first surface 402 of the recess may be equal to a width W2 of the second surface 404 of the recess. For example, the sidewall 406 may be closer to the second underfill layer 420 in the first direction than the first surface 402.

One of a plurality of recesses of the interposer 400 may be further outside than an interposer top pad 414, a first connection pad 112, and a first chip connection terminal 115, which are formed on the interposer 400.

For example, the first surface 402 of one of the recesses may be further outside than an outermost interposer top pad 414O among the interposer top pads 414, an outermost first connection pad 112O among the first connection pads 112, and an outermost first chip connection terminal 115O among the first chip connection terminals 115.

Here, the outside may refer to a direction from the outermost interposer top pad 414O, the outermost first connection pad 112O, and the outermost first chip connection terminal 115O to the side wall 406 of the interposer 400. One of the recesses of the interposer 400 may be separated, by a certain width W4 in the first direction, from a portion that protrudes furthest outside (or, e.g., outward) among the outermost interposer top pad 414O, the outermost first connection pad 112O, and the outermost first chip connection terminal 115O.

For example, as shown in FIGS. 1 and 2, the portion that protrudes furthest outside among the outermost interposer top pad 414O, the outermost first connection pad 112O, and the outermost first chip connection terminal 115O may be a bulging portion of the outermost first chip connection terminal 115O. Accordingly, the first surface 402 of the recess may be separated from the bulging portion of the outermost first chip connection terminal 115O by the certain width W4 in the first direction. For example, the width W2 of the second surface 404 of the recess may be less than a first direction distance (e.g., the sum of W2 and W4) from the side wall 406 of the interposer 400 to an outermost connection terminal among a plurality of connection terminals. Here, the connection terminals may refer to the first chip connection terminals 115. The outermost connection terminal may refer to the outermost first chip connection terminal 115O.

Referring to FIG. 1, another one of the recesses of the interposer 400 may be further outside than an outermost interposer top pad 414O, an outermost third connection pad 312O, and an outermost third chip connection terminal 315O. Similarly, another one of the recesses of the interposer 400 may be separated, by the certain width W4 in the first direction, from a portion that protrudes furthest outside among the outermost interposer top pad 414O, the outermost third connection pad 312O, and the outermost third chip connection terminal 315O.

In some embodiments of the present inventive concept, the certain width W4 between the outermost third chip connection terminal 315O and the first surface 402 of the recess may be about 100 μm to about 200 μm. In some embodiments of the present inventive concept, the certain width W4 between the outermost third chip connection terminal 315O and the first surface 402 of the recess may be about 120 μm to about 180 μm. In some embodiments of the present inventive concept, the certain width W4 between the outermost third chip connection terminal 315O and the first surface 402 of the recess may be about 140 μm to about 160 μm.

The first underfill layer 500 may include a first underfill layer contact surface contacting the second surface 404 of the recess. In some embodiments of the present inventive concept, the width W2 of the second surface 404 of the recess may be at least about 100 μm greater than a width W3 of the first underfill layer contact surface. In some embodiments of the present inventive concept, the width W2 of the second surface 404 of the recess may be at least about 60 μm greater than the width W3 of the first underfill layer contact surface. In some embodiments of the present inventive concept, the width W2 of the second surface 404 of the recess may be at least about 20 μm greater than the width W3 of the first underfill layer contact surface.

In some embodiments of the present inventive concept, the width W2 of the second surface 404 of the recess may be about 800 μm to about 1200 μm. In some embodiments of the present inventive concept, the width W2 of the second surface 404 of the recess may be about 900 μm to about 1100 μm.

As shown in FIG. 2, when a recess having the first surface 402 and the second surface 404 is formed in a corner (or, e.g., side portion) of the interposer 400 of the semiconductor package 10, a force applied to the corner of the interposer 400 may be dispersed. Generally, the greatest force may be applied to a corner (or, e.g., side portion) of the interposer, and accordingly, cracks may occur. The force applied to a corner (or, e.g., side portion) of the interposer 400 may be dispersed by forming a groove, such as a recess, in the corner (or, e.g., side portion) of the interposer 400, and therefore, the stability of the semiconductor package 10 may be increased. The reliability of the semiconductor package 10 may be increased via such corner avoidance.

FIGS. 3 to 6 are cross-sectional views illustrating semiconductor packages and enlarged cross-sectional views of a region EX2 in FIG. 1, according to some embodiments of the present inventive concept.

FIG. 3 is an enlarged cross-sectional view of the region EX2 of the semiconductor package 10, according to an embodiment of the present inventive concept.

Referring to FIG. 3, a recess of the interposer 400 may have a step difference (e.g., the width W1) between the bottom surface of the interposer 400 and the second surface 404 of the recess, and the first surface 402 of the recess may be in contact with the second surface 404 thereof at about a right angle. The step difference between the bottom surface of the interposer 400 and the second surface 404 of the recess may be equal to the width W1 of the first surface 402 of the recess. The step difference between the bottom surface of the interposer 400 and the second surface 404 of the recess has been described above with reference to FIG. 2.

The first surface 402 of the recess may be surrounded by the first underfill layer 500. For example, the first surface 402 of the recess may be completely surrounded by the first underfill layer 500. A remaining portion other than the portion of the second surface 404 of the recess, which is in contact with the first underfill layer contact surface (e.g., the portion with the width W3), may be covered with the second underfill layer 420. In other words, the second surface 404 of the recess may be in contact with the first underfill layer 500 and the second underfill layer 420. The width W1 of the first surface 402 of the recess may be greater than the width W2 of the second surface 404 of the recess.

In some embodiments of the present inventive concept, the width W3 of the first underfill layer contact surface may be equal to the width W1 of the first surface 402 of the recess. In this case, the second underfill layer 420 may surround the first underfill layer 500 and the side wall 406 of the interposer 400.

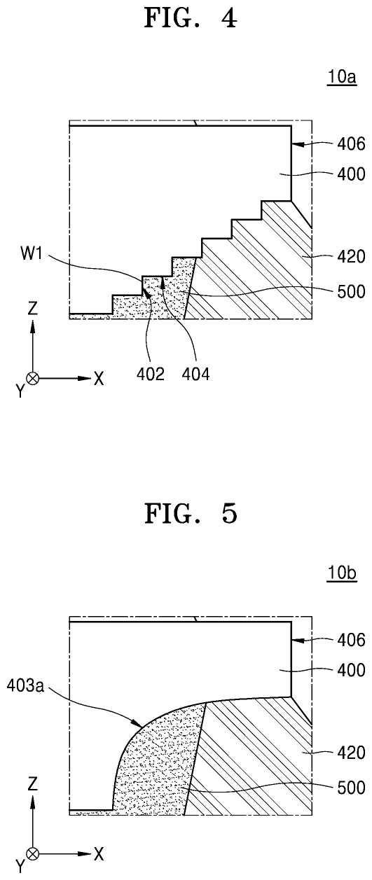

FIG. 4 is an enlarged cross-sectional view of the region EX2 of a semiconductor package 10a, according to an embodiment of the present inventive concept.

Referring to FIG. 4, a recess of the interposer 400 may have a step difference increasing toward the side wall 406 of the interposer 400. The recess of the interposer 400 may have a stair shape having a plurality of step differences W1. The recess of the interposer 400 may include a plurality of first surfaces 402 and a plurality of second surfaces 404. Here, each step difference W1 may refer to a level difference in the vertical direction between the bottommost surface of the interposer 400 and a second surface 404 of the recess.

One of the first surfaces 402 may be in contact with one of the second surfaces 404 at about a right angle. Two neighboring ones of the second surfaces 404 may have a step difference W1 in the vertical direction, and two other neighboring ones of the second surfaces 404 may have the same step difference W1 in the vertical direction. For example, the second surfaces 404 of the recess may have the same step difference W1.

The first underfill layer 500 may surround some of the first surfaces 402 of the recess. The first underfill layer 500 might not be in contact with the other first surfaces 402 of the recess, which are close to the side wall 406 of the interposer 400. The first underfill layer 500 may completely cover some of the second surfaces 404 of the recess and only partially cover one of the second surfaces 404 of the recess. The first underfill layer 500 might not cover the other second surfaces 404 of the recess.

FIG. 5 is an enlarged cross-sectional view of the region EX2 of a semiconductor package 10b, according to an embodiment of the present inventive concept.

Referring to FIG. 5, a recess of the interposer 400 may include a boundary surface 403a. The boundary surface 403a may be curved. The boundary surface 403a may have a concave shape having a step difference with respect to the bottom surface of the interposer 400 in the vertical direction, and the step difference may increase toward the side wall 406 of the interposer 400. The boundary surface 403a may be a part of a circle or an ellipse. The step difference between the bottom surface of the interposer 400 and the boundary surface 403a may increase toward the side wall 406 of the interposer 400, and a rate of the increase in the step difference may gradually decrease.

A portion of the boundary surface 403a may be in contact with the first underfill layer 500, and the other portion of the boundary surface 403a might not be in contact with the first underfill layer 500. The other portion of the boundary surface 403a may be covered with the second underfill layer 420, The boundary surface 403a may extend from the bottom surface of the interposer 400 to the side wall 406 of the interposer 400. The first underfill layer 500 and the second underfill layer 420 might not be in contact with the side wall 406 of the interposer 400. Although the boundary surface 403a is concave and curved in FIG. 5, the present inventive concept is not necessarily limited thereto. The boundary surface 403a may be convex and curved.

When a recess including the boundary surface 403a is formed in the semiconductor package 10b, a force applied to a corner of the interposer 400 may be dispersed. Because the force is dispersed along the boundary surface 403a, cracks that may occur in the semiconductor package 10 may be prevented.

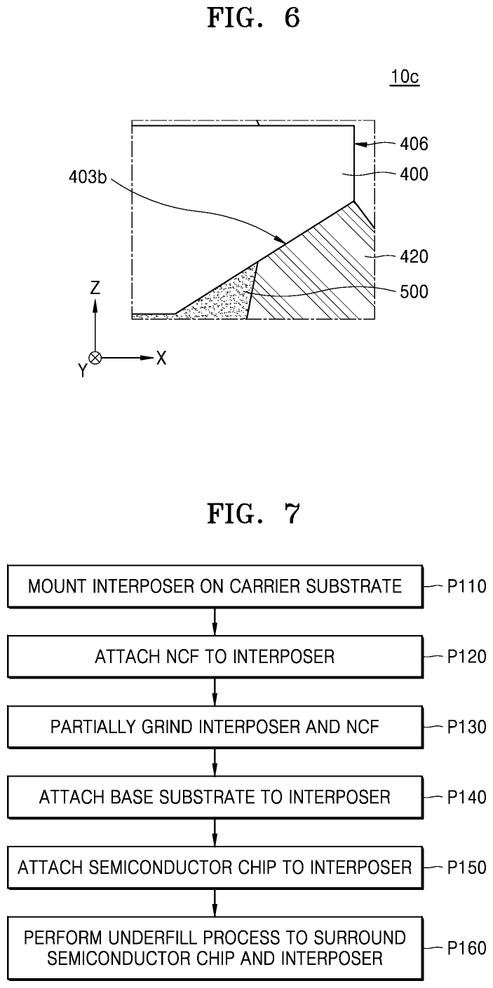

FIG. 6 is an enlarged cross-sectional view of the region EX2 of a semiconductor package 10c, according to an embodiment of the present inventive concept.

Referring to FIG. 6, a recess of the interposer 400 may include a boundary surface 403b. The boundary surface 403b may be flat and oblique to the first or second direction. The boundary surface 403b of the recess may have a step difference with respect to the bottom surface of the interposer 400, and the step difference may increase toward the side wall 406 of the interposer 400. The recess may extend in a diagonal direction to the bottom surface of the interposer 400. For example, the boundary surface 403b may connect the bottom surface of the interposer 400 to the sidewall 406 and may be slanted at an angle with respect to the bottom surface of the interposer 400.

The boundary surface 403b of the recess may extend from the bottom surface of the interposer 400 to the side wall 406 of the interposer 400, The step difference between the boundary surface 403b of the recess and the bottom surface of the interposer 400 may increase toward the side wall 406 of the interposer 400, and the increase in the step difference may be constant. In some embodiments of the present inventive concept, the boundary surface 403b of the recess may form an angle of about 45 degrees with respect to the first direction or the second direction. However, the present inventive concept is not necessarily limited thereto.

When a recess including the boundary surface 403b is formed in the semiconductor package 10c, a force applied to a corner of the interposer 400 may be dispersed along the boundary surface 403b. Accordingly, the productivity of the semiconductor package 10c may be increased.

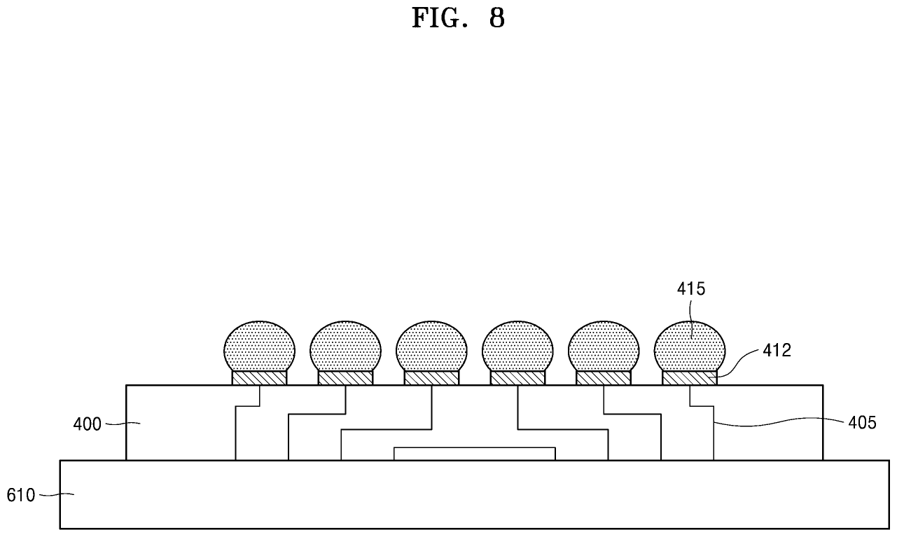

FIG. 7 is a flowchart of a method of manufacturing a semiconductor package, according to an embodiment of the present inventive concept. FIGS. 8 to 12 are cross-sectional views of stages in a method of manufacturing a semiconductor package, according to an embodiment of the present inventive concept.

Referring to FIGS. 7 and 8, the interposer 400 may be mounted on a carrier substrate 610 in operation P110. The top surface of the interposer 400 may face the carrier substrate 610. The interposer 400 may include a plurality of interposer interconnection lines 405, a plurality of interposer bottom pads 412, and a plurality of interposer connection terminals 415.

The carrier substrate 610 may include a material having stability with respect to subsequent processes. In some embodiments of the present inventive concept, in the case where the carrier substrate 610 is separated and removed by laser ablation, the carrier substrate 610 may include a transparent substrate. In some embodiments of the present inventive concept, in the case where the carrier substrate 610 is separated and removed by heating, the carrier substrate 610 may include a heat resistant substrate.

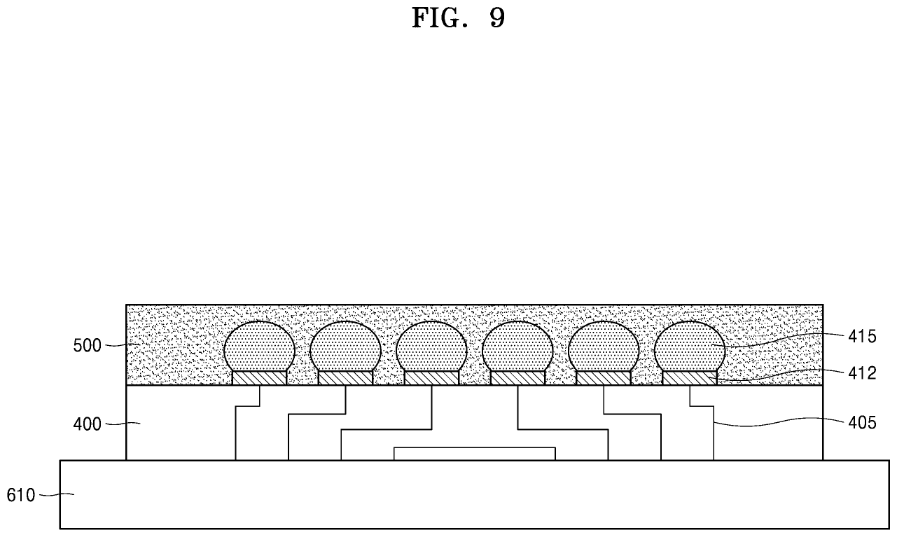

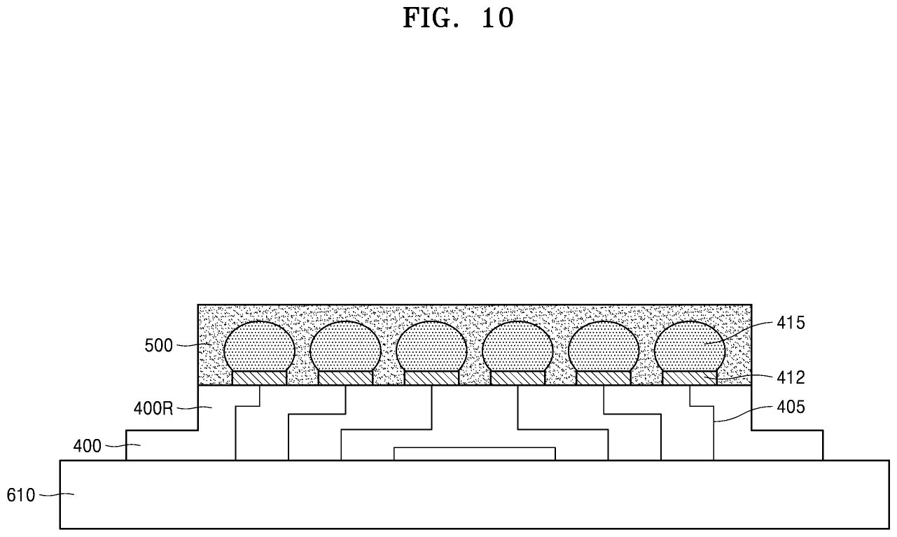

Referring to FIGS. 7 and 9, the first underfill layer 500 may be attached to the interposer 400 in operation P120. The first underfill layer 500 may be attached to the bottom surface of the interposer 400. The bottom surface of the interposer 400 may be opposite the top surface of the carrier substrate 610. The first underfill layer 500 may include an NCF and may cover the bottom surface of the interposer 400, the interposer bottom pads 412, and the interposer connection terminals 415.

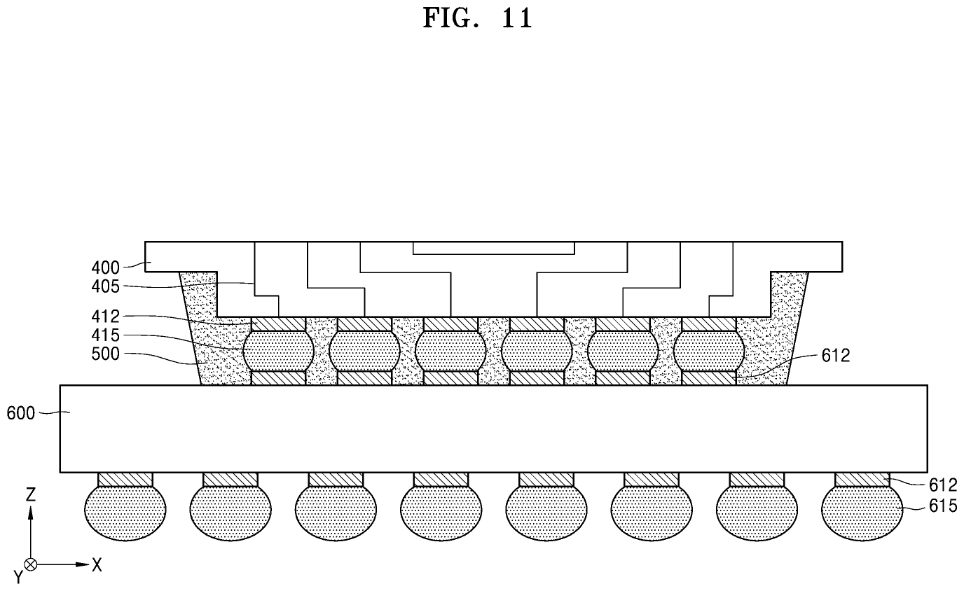

Referring to FIGS. 7 and 10, the interposer 400 and the first underfill layer 500 may be partially ground in operation P130. A recess 400R may be formed in a corner (or, e.g., side portion) of the interposer 400 by a grinding process. The grinding process may be performed to a depth that is greater than or equal to half the thickness of the interposer 400. For example, the grinding process may be performed using a blade saw, a dicer, a laser, or the like.

Referring to FIGS. 7 and 11, the base substrate 600 may be attached to the interposer 400 in operation P140. Here, the first underfill layer 500 may be transformed by thermal compression such that the side wall of the first underfill layer 500 is oblique, as shown in FIG. 11. However, the present inventive concept is not necessarily limited thereto. The first underfill layer 500 may be transformed to have a bulging side wall. For example, the first underfill layer 500 may be transformed to have a curved sidewall. Before operation P140, the carrier substrate 610 may be removed, and the interposer 400 may be turned upside down. A plurality of base substrate pads 612 of the base substrate 600 may be respectively connected to the interposer connection terminals 415. The interposer 400 may be electrically connected to the base substrate 600 by the interposer connection terminals 415. The space between the interposer 400 and the base substrate 600 may be insulated and filled by the first underfill layer 500 therebetween. The base substrate pads 612, the interposer connection terminals 415, and the interposer bottom pads 412 may be referred to as second connection terminals. The first underfill layer 500 may cover the second connection terminals.

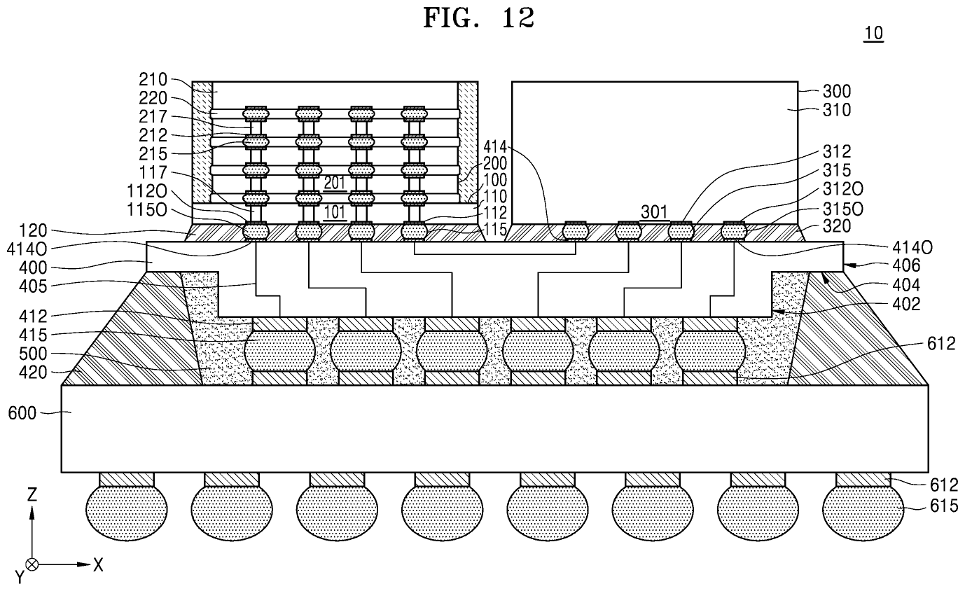

Referring to FIGS. 7 and 12, a semiconductor chip may be attached to the interposer 400 in operation P150. Here, the semiconductor chip may include at least one stack structure ST and the third semiconductor chip 300. The stack structure ST may include the first semiconductor chip 100 and the second semiconductor chips 200. The first to third semiconductor chips 100, 200, and 300 may be electrically connected by the interposer 400 to one another and to the base substrate 600.

Referring to FIGS. 1 and 7, an underfill process may be performed to surround the semiconductor chip and the interposer 400 in operation P160. The second underfill layer 420 may be formed by the underfill process such that the second underfill layer 420 fills a space between the interposer 400 and the base substrate 600, The second underfill layer 420 may surround the first underfill layer 500. The second underfill layer 420 may include underfill resin. The second underfill layer 420 may include a different material than the first underfill layer 500. The third and fourth underfill layers 120 and 320 may be formed by the underfill process. The third underfill layer 120 may fill a space between the first semiconductor chip 100 and the interposer 400, and the fourth underfill layer 320 may fill a space between the third semiconductor chip 300 and the interposer 400.

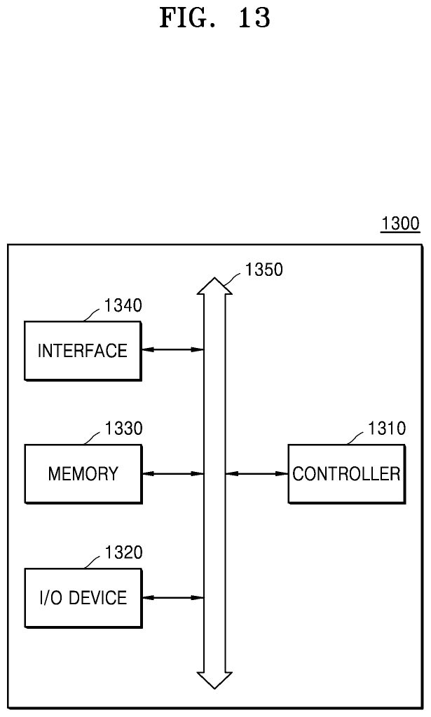

FIG. 13 is a block diagram of a system of a semiconductor package, according to an embodiment of the present inventive concept.

Referring to FIG. 13, a system 1300 may include a controller 1310, an input/output (I/O) device 1320, a memory 1330, an interface 1340, and a bus 1350.

The system 1300 may include a mobile system or a system that transmits or receives information. In some embodiments of the present inventive concept, the mobile system may include a portable computer, a web tablet, a mobile phone, a digital music player, or a memory card.

The controller 1310 may control execution programs in the system 1300 and may include a microprocessor, a digital signal processor, a microcontroller, or the like.

The I/O device 1320 may be used to input data to or output data from the system 1300. The system 1300 may be connected to an external device, e.g., a personal computer (PC) or a network, and may exchange data with the external device, by using the I/O device 1320. For example, the 110 device 1320 may include a touch pad, a keyboard, or a display.

The memory 1330 may store data for the operation of the controller 1310 or data processed by the controller 1310. The memory 1330 may include at least one of the semiconductor packages 10, 10a, 10b, and 10c described above according to some embodiments of the present inventive concept.

The interface 1340 may correspond to a data transmission passage between the system 1300 and an external device. The controller 1310, the I/O device 1320, the memory 1330, and the interface 1340 may communicate with one another through the bus 1350.

While the present inventive concept has been described with reference to embodiments thereof, it will be understood by those of ordinary skill in the art that various changes in form and details may be made thereto without departing from the spirit and scope of the present inventive concept

What is claimed is:

1. A semiconductor package comprising:
a base substrate;
an interposer disposed on the base substrate, wherein the interposer includes a plurality of recesses in a bottom surface thereof;
a semiconductor chip disposed on the interposer;
a plurality of interposer connection terminals between the interposer and the base substrate, wherein the plurality of interposer connection terminals electrically connect the interposer to the base substrate; and
a first underfill layer disposed between the interposer and the base substrate, wherein the first underfill layer at least partially surrounds the plurality of interposer connection terminals,
wherein the first underfill layer at least partially surrounds a side surface of each of the plurality of recesses and has a slope declining from the bottom surface of the interposer to a top surface of the base substrate.

2. The semiconductor package of claim 1, wherein
each of the plurality of recesses is formed in a lower corner of the interposer and is defined by a first surface and a second surface of the interposer, wherein the first and second surfaces extend in different directions from each other, and
wherein the second surface of each of the plurality of recesses has a step difference with respect to the bottom surface of the interposer and faces the base substrate.

3. The semiconductor package of claim 2, wherein the step difference of the second surface is less than or equal to half of a thickness of the interposer.

4. The semiconductor package of claim 2, wherein the first surface of each of the plurality of recesses is further outward than the plurality of interposer connection terminals in a first direction that is parallel with a top surface of the interposer.

5. The semiconductor package of claim 1, wherein a side wall of the interposer protrudes beyond a side wall of the first underfill layer in a lateral direction.

6. The semiconductor package of claim 1, further comprising a second underfill layer between the base substrate and the interposer, wherein the second underfill layer at least partially surrounds a side surface of the first underfill layer.

7. The semiconductor package of claim 1, wherein each of the plurality of recesses is defined by a surface of the interposer, wherein the surface of the interposer has a curved profile from the bottom surface of the interposer to a side wall of the interposer.

8. The semiconductor package of claim 1, wherein each of the plurality of recesses is defined by a surface of the interposer, wherein the surface of the interposer extends from the bottom surface of the interposer to a side wall of the interposer and is oblique to the bottom surface of the interposer.

9. The semiconductor package of claim 1, wherein each of the plurality of recesses has a stair shape having a plurality of step differences, with respect to the bottom surface of the interposer; increasing toward a side wall of the interposer.

10. A semiconductor package comprising:
a base substrate;
an interposer disposed on the base substrate, wherein the interposer includes a plurality of recesses in a bottom surface thereof;
a core die stack disposed on the interposer;
a plurality of interposer connection terminals disposed between the interposer and the base substrate, wherein the plurality of interposer connection terminals electrically connect the interposer to the base substrate;
a first underfill layer disposed between the interposer and the base substrate, wherein the first underfill layer at least partially surrounds the plurality of interposer connection terminals; and
a second underfill layer disposed between the base substrate and the interposer, wherein the second underfill layer at least partially surrounds a side surface of the first underfill layer,
wherein each of the plurality of recesses is formed in a lower corner of the interposer and is defined by a first surface and a second surface of the interposer, wherein the first and second surfaces extend in different directions from each other, and the second surface of each of the plurality of recesses has a step difference with respect to the bottom surface of the interposer and faces the base substrate,
a side wall of the interposer protrudes beyond a side wall of the first underfill layer in a lateral direction, and
a width of the second surface is about 800 μm to about 1,200 μm.

11. The semiconductor package of claim 10, wherein a width of a bottom surface of the first underfill layer is less than a width of a top surface of the first underfill layer.

12. The semiconductor package of claim 10, wherein
the first underfill layer includes a first underfill layer contact surface contacting the second surface of each of the plurality of recesses, and
the width of the second surface is at least about 20 μm greater than a width of the first underfill layer contact surface.

13. The semiconductor package of claim 10, further comprising
a plurality of first connection terminals electrically connecting the core die stack to the interposer, and
wherein the width of the second surface of each of the plurality of recesses is less than a distance in a first direction from the side wall of the interposer to an outermost one of the plurality of first connection terminals, wherein the first direction is parallel with a top surface of the interposer.

14. The semiconductor package of claim 10, wherein the step difference of the second surface with respect to the bottom surface of the interposer is about 45 μm to about 65 μm.

15. The semiconductor package of claim 10, wherein the first underfill layer includes a non-conductive film (NCO.

16. The semiconductor package of claim 15, wherein the second underfill layer covers a portion of the second surface of each of the plurality of recesses.

17. The semiconductor package of claim 10, wherein the second underfill layer includes a material different from a material of the first underfill layer.

18. A semiconductor package comprising:
a base substrate;
a silicon interposer attached to the base substrate and including a plurality of recesses, wherein each of the plurality of recesses includes a first surface and a second surface, wherein the first surface is substantially perpendicular to a first direction, and wherein the second surface has a step difference from a bottom surface of the silicon interposer and faces the base substrate;
at least one stack structure attached to the silicon interposer and including a first semiconductor chip and a plurality of second semiconductor chips stacked on the first semiconductor chip in a vertical direction, wherein the first semiconductor chip includes a first semiconductor substrate and a plurality of first through electrodes passing through the first semiconductor substrate, and wherein each of the plurality of second semiconductor chips includes a second semiconductor substrate and a plurality of second through electrodes electrically connected to the plurality of first through electrodes;
a plurality of third semiconductor chips attached to the silicon interposer and separated from the at least one stack structure in a horizontal direction;
a first underfill layer disposed between the silicon interposer and the base substrate, wherein the first underfill layer bonds the silicon interposer to the base substrate and includes a first underfill layer contact surface contacting the second surface of each of the plurality of recesses; and
a second underfill layer at least partially surrounding a side surface of the first underfill layer,
wherein the step difference of the second surface is less than or equal to half of a thickness of the silicon interposer.

19. The semiconductor package of claim 18, wherein
the first semiconductor chip includes a high bandwidth memory (HBM) control die, wherein each of the plurality of second semiconductor chips includes a dynamic random access memory (DRAM) die, and
wherein at least one of the plurality of third semiconductor chips includes a plurality of functional blocks, and at least another one of the plurality of third semiconductor chips includes one functional block.

20. The semiconductor package of claim 18, wherein
a width of the first surface of each of the plurality of recesses is about 45 μm to about 65 μm, and
a width of the second surface of each of the plurality of recesses is at least about 20 μm greater than a width of the first underfill layer contact surface.
